(19) United States
(12) Patent Application Publication
(10) Pub. No.: US 2011/0203328 A1
(43) Pub. Date: Aug. 25, 2011

(54) ELECTRICALLY AND MANUALLY LOCKABLE CONTAINER SYSTEM

(75) Inventors: Gil Vilkomirski, Petach-Tiqwa (IL); Iftach Galler, Kfar-Hess (IL)

(73) Assignee: THE STANLEY WORKS ISRAEL LTD., Rosh Ha'Ayin (IL)

(21) Appl. No.: 12/718,801

(22) Filed: Mar. 5, 2010

Related U.S. Application Data
(60) Provisional application No. 61/307,247, filed on Feb. 23, 2010.

(51) Int. Cl. E05B 65/00; E05B 51/00; E05B 47/00; H03M 11/00

(52) U.S. Cl. 70/57.1; 70/159; 341/22

(57) ABSTRACT

An electrically and manually lockable container system that includes a container having a container portion and a cover. The cover can be selectively disposed in locked or unlocked conditions relative to the container portion. The container system carries a lock system that includes a latch member that is movable between a locked and unlocked configuration. In the locked configuration, the latch member prevents the cover from being moved from the locked to the unlocked condition. In the unlocked configuration, the latch member permits the cover to be moved from the locked to the unlocked condition. The lock system includes a motor operatively connected with the latch member and a controller that operates the motor to move the latch member between the locked and unlocked configurations. The lock system also includes a manual key arrangement that enables the latch member to be manually moved between the locked and unlocked configuration.

### CROSS REFERENCE TO RELATED APPLICATIONS

This application claims priority and benefit under 35 U.S.C. §119(e) to U.S. Provisional Patent Application No. 61/307,247, entitled “Electrically and Manually Lockable Container System”, filed on Feb. 23, 2010. The content of that application is incorporated herein in its entirety by reference.

### BACKGROUND OF THE INVENTION

### Field of the Invention

The present invention relates to a tool container, and, more particularly to an electronic tool container which carries an alarm system.

Numerous tool container assemblies are known in the art. These tool container assemblies can be easily transported from one place to another, and store tools that are needed for accomplishing a task. However, theft of tools from the container assemblies is often a problem.

### SUMMARY

One aspect of the invention provides an electrically and manually lockable container system. The container system has a container that includes a container portion and a cover. The container portion has a storage space and defines an upwardly facing opening into the storage space. The cover is movable between a closed position wherein the cover substantially covers the upwardly facing opening and an open position wherein the upwardly facing opening is substantially exposed. The cover is arranged to be selectively disposed in locked or unlocked conditions relative to the container portion. A lock system is carried by the container system. The lock system comprises a latch member that is movable between a locked and unlocked configuration, wherein in the locked configuration, the latch member is configured to prevent the cover from being moved from the locked to the unlocked condition relative to the container and wherein in the unlocked configuration, the latch member is configured to permit the cover to be moved from the locked to the unlocked condition relative to the container portion. The lock system includes a motor operatively connected with the latch member and a controller electrically operable to operate the motor to move the latch member between the locked and unlocked configurations. The lock system also includes a manual key arrangement to enable the latch member to be manually moved between the locked and unlocked configuration.

These and other aspects of the present invention, as well as the methods of operation and functions of the related elements of structure and the combination of parts and economies of manufacture, will become more apparent upon consideration of the following description and the appended claims with reference to the accompanying drawings, all of which form a part of this specification, wherein like reference numerals designate corresponding parts in the various figures. In one embodiment, the figures herein may be considered drawn to scale. It is to be expressly understood, however, that the drawings are for the purpose of illustration and description only and are not intended as a definition of the limits of the invention. As used in the specification and in the claims, the singular form of “a”, “an”, and “the” include plural referents unless the context clearly dictates otherwise.

### BRIEF DESCRIPTION OF THE DRAWINGS

FIG. 1 is a perspective view of an electrically and manually lockable container system in accordance with one embodiment;

FIG. 2 is an exploded view of the electrically and manually lockable container system;

FIG. 3 is a detailed view from the top of a user interface of the electrically and manually lockable container system in accordance with an embodiment;

FIG. 4 is a detailed view from the bottom of the lock system of the electrically and manually lockable container system in accordance with an embodiment;

FIG. 5 is a partial cross-sectional view of the electrically and manually lockable container system in accordance with an embodiment;

FIG. 6 is a partial cross-sectional view of the electrically and manually lockable container system wherein the lock system is in a locked configuration in manual mode in accordance with an embodiment;

FIG. 7 is a detailed view of the electrically and manually lockable container system wherein the lock system is in a locked configuration in accordance with an embodiment;

FIG. 8 is a partial cross-sectional view of the electrically and manually lockable container system wherein the lock system is in an unlocked configuration in manual mode in accordance with an embodiment;

FIG. 9 is a detailed view of the electrically and manually lockable container system wherein the lock system is being moved to the unlocked position in the manual mode in accordance with an embodiment;

FIG. 10 is a detailed view of the electrically and manually lockable container system wherein the lock system is in the unlocked configuration in accordance with an embodiment;

FIG. 11 is a partial cross-sectional view of the electrically and manually lockable container system wherein the lock system is in a locked configuration in electronic mode in accordance with an embodiment;

FIG. 12 is a partial cross-sectional view of the electrically and manually lockable container system wherein the lock system is in an unlocked configuration in electronic mode in accordance with an embodiment; and

FIGS. 13A-13C are detailed views of a latch structure of the electrically and manually lockable container system in accordance with an embodiment; and

FIGS. 14A-14B are detailed views of latch member and motor of the electrically and manually lockable container system in accordance with an embodiment.

### DETAILED DESCRIPTION OF THE INVENTION

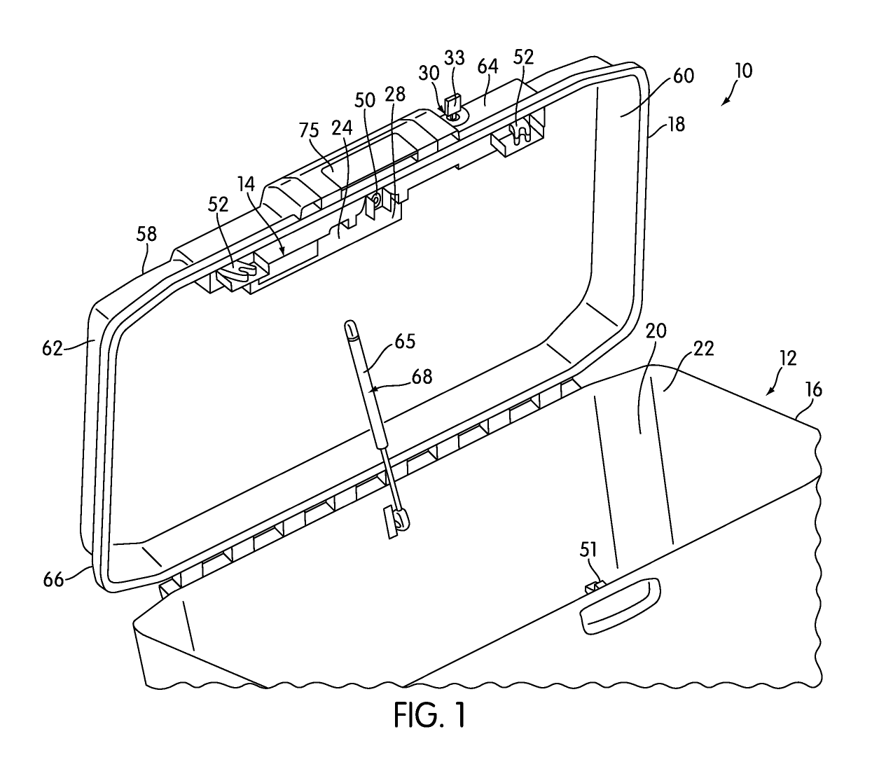

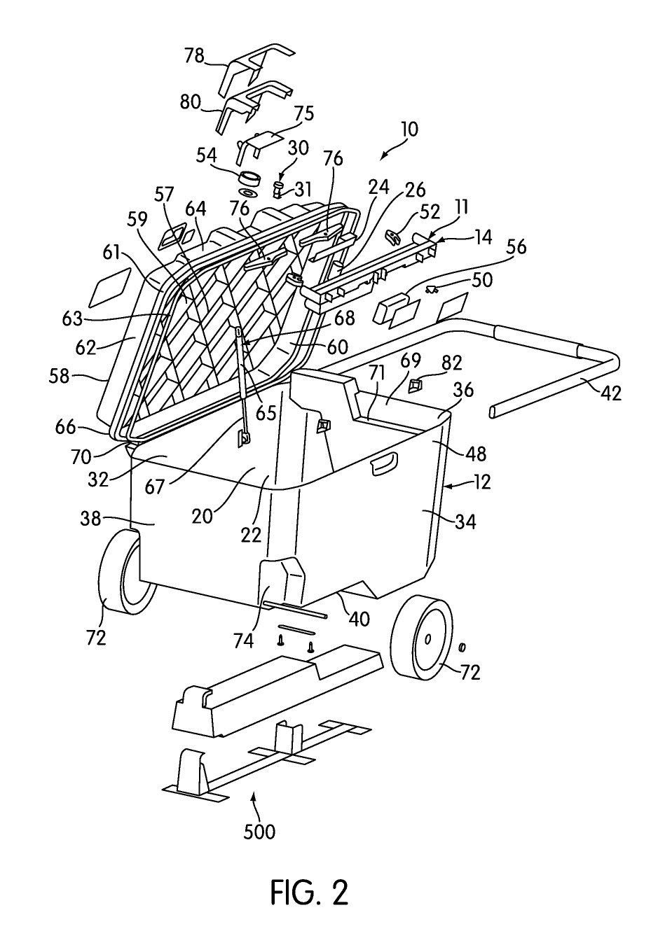

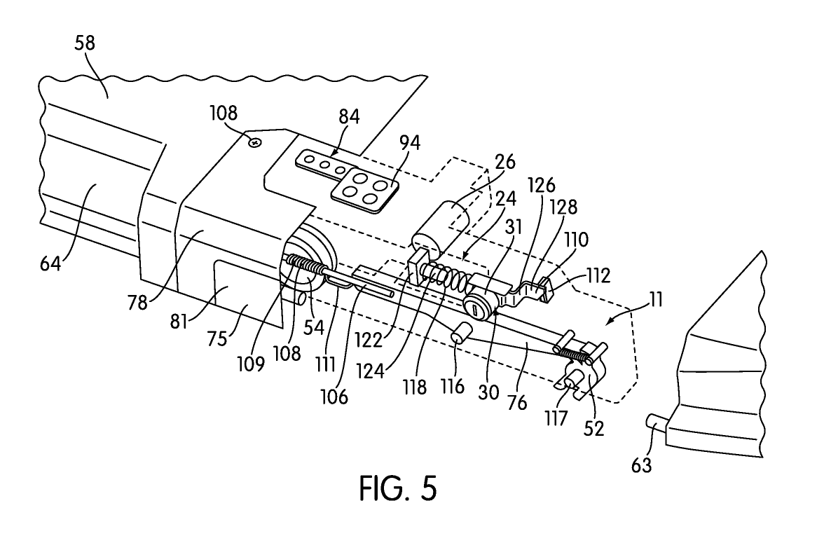

FIGS. 1 and 2 show an electrically and manually lockable container system 10 in accordance with an embodiment of the present invention. The electrically and manually lockable container system 10 includes a container 12. The container 12 has a container portion 16 and a cover 18. The container portion 16 includes a storage space 20 and defines an upwardly facing opening 22 into the storage space 20. The cover 18 is movable between a closed position wherein the cover 18 substantially covers the upwardly facing opening 22 and an open position wherein the upwardly facing opening 22 is substantially exposed. The cover 18 is arranged to be selectively locked and unlocked relative to the container 12. The lock system 14 is carried by the container system 10, the lock system 14 includes a latch member 24 movable between a locked and unlocked configuration, wherein in the locked configuration, the latch member 24 is configured to prevent the cover 18 from being moved from the locked to the unlocked condition relative to the container 12 and wherein in the unlocked configuration, the latch member 24 is configured to permit the cover 18 to be moved from the locked to the unlocked condition relative to the container 12. As such, when the lock system 14 is in a locked state, the cover 18 is prevented from being moved to enable access to the opening 22 into the storage space 20. The lock system 14 also includes a motor 26 (see FIG. 5) operatively connected with the latch member 24. The lock system 14 also includes a controller 28 (see FIG. 4) electrically operable to operate the motor 26 to move the latch member 24 between the locked and unlocked configurations. The lock system 14 also has a manual key arrangement 30 to enable the latch member 24 to be manually moved between the locked and unlocked configuration. When the lock system 14 is in an unlocked state, the cover is permitted to be moved to enable access to the opening 22 into the storage space 20.

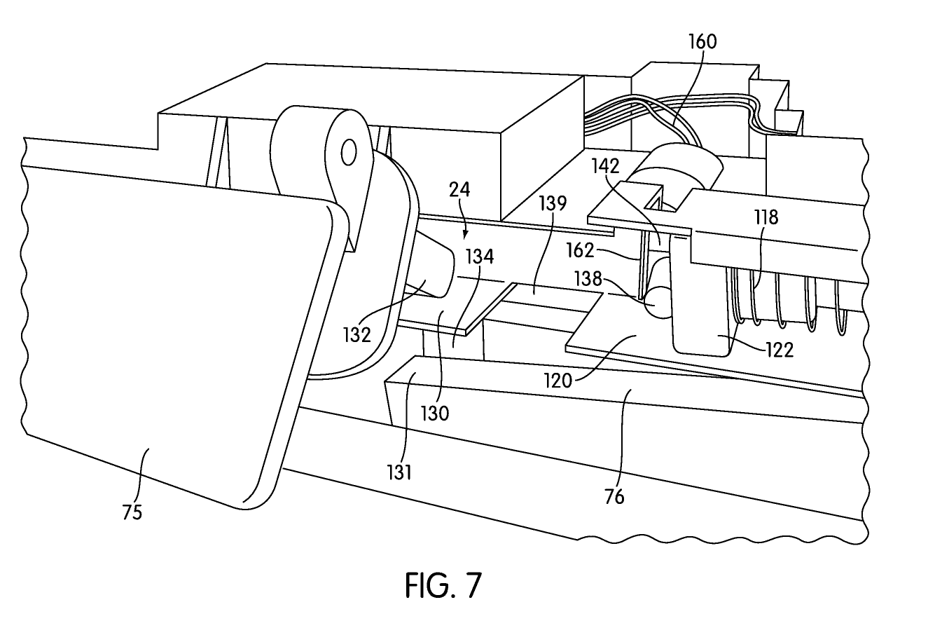

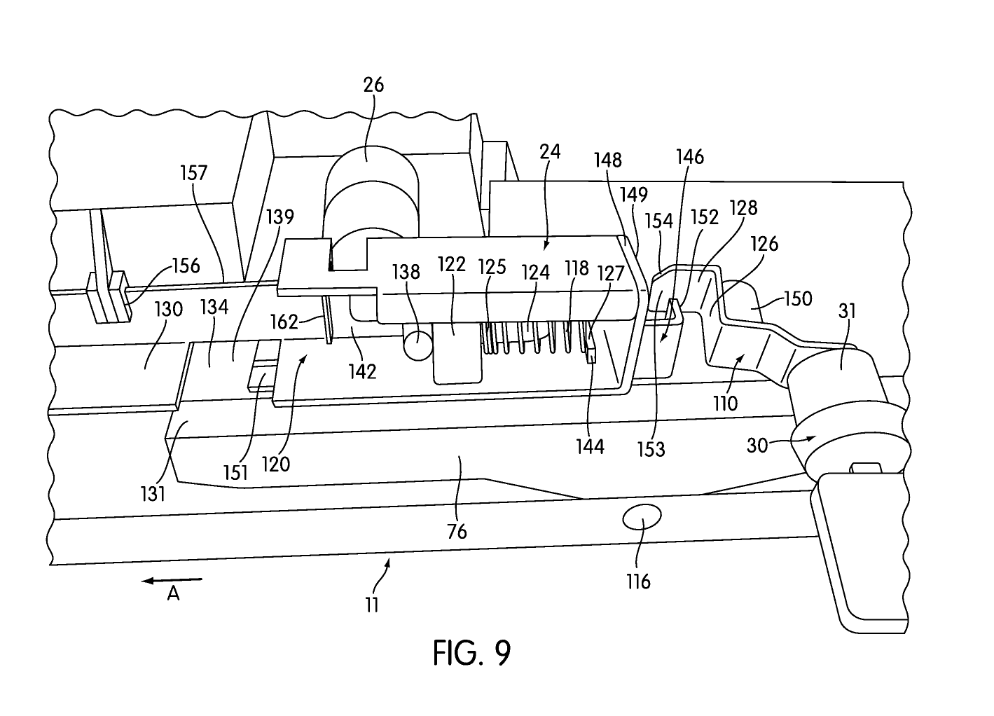

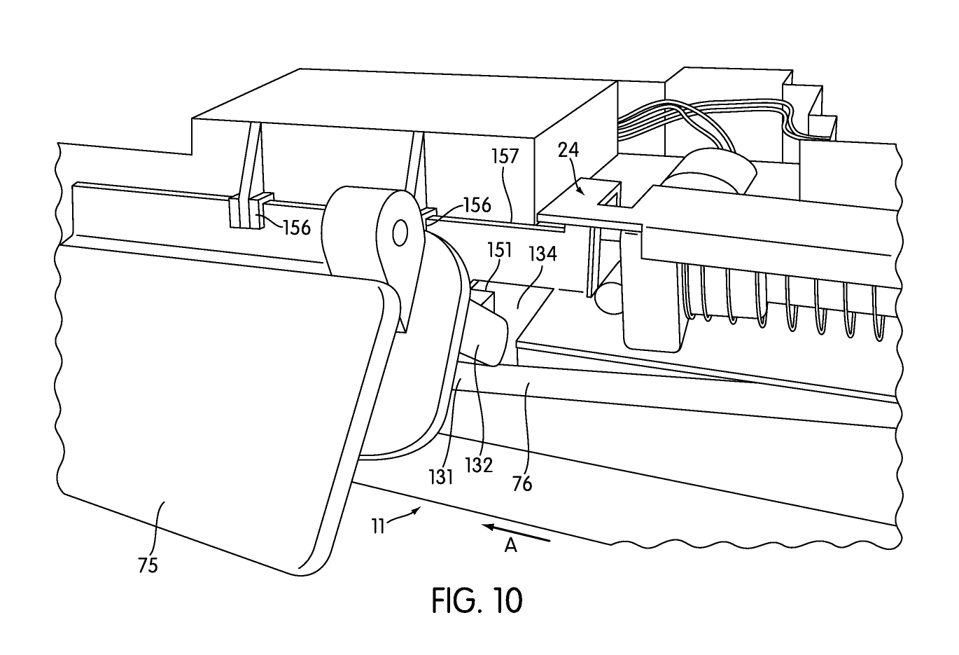

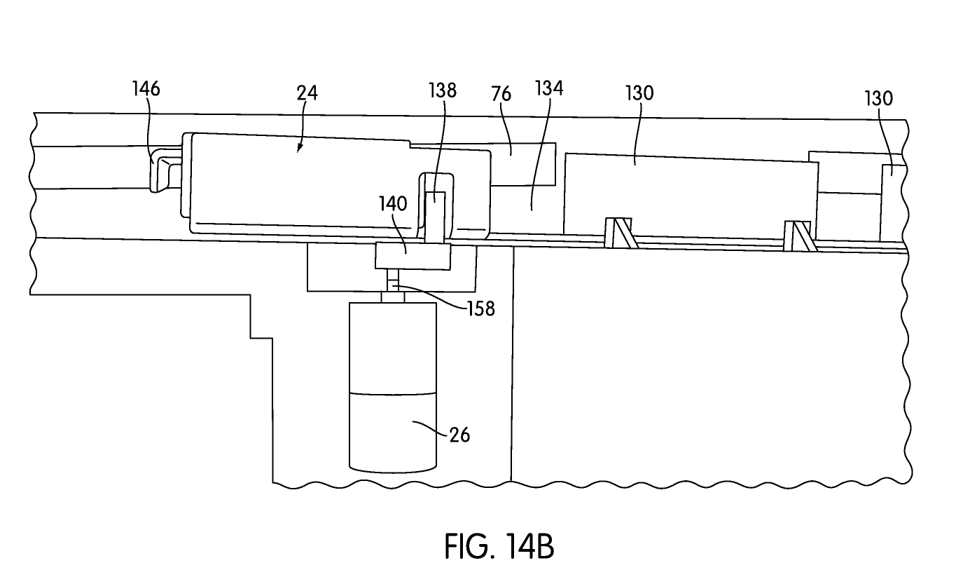

The latch member 24, in one embodiment, includes a receiving portion 120 that receives a sliding member 122 having a finger 124, as shown in FIG. 9. In the embodiment shown in FIG. 9, a spring 118 is attached at one end 125 to the finger 124 of the sliding member 122 and an other end 127 of the spring 118 is attached to an inner structure 144 (see FIG. 9), taking the form of a forked structure, of the latch member 24. The receiving portion 120 of the latch member 24 may also receive a finger 138 of an eccentric 140 (see FIGS. 14A and 14B) operatively connected to the motor 26. In the embodiment shown in FIG. 9, the finger 138 is received within an opening 142 in the receiving portion 120 of the latch member 24. The spring 118 is constructed and arranged to push the sliding member 122 against the finger 138 of the eccentric 140 when the spring 118 is in a relaxed (or less stressed) state. A flange 162 is also disposed in the receiving portion 120 of the latch member 24 and is constructed and arranged to contact the finger 138 of the eccentric 140 when the finger 138 of the eccentric 140 is in the position shown in FIG. 7. Referring back to FIG. 9, the receiving portion 120 is defined on the right by a side wall 148 having an outer surface 149. A lip 146 (see FIG. 9), which is L-shaped in one embodiment, extends from the side wall 148 of the latch member 24. The latch member 24 may be provided with a pair of openings 139 (one is shown in FIG. 9) and blocking portions 130. The openings 139 and blocking portions 130 will be described in more detail later. The latch member 24 may be made of metal, although other materials may be used.

In one embodiment, the lock system 12 includes a latch structure 52 (see FIG. 5) that is movable between an engaged position wherein the latch structure 52 is engaged between the container portion 16 and the cover 18 to prevent the cover 18 from being moved to the open position, and a disengaged position wherein the latch structure 52 is not engaged between the container portion 16 and the cover 18 to permit the cover 18 to be moved to the open position. In the engaged position, the latch structure 24 may be engaged with engaging structures 82 (see FIG. 2) located on the container 16. The engaging structures 82 may be attached to the container 16 using screws, pins, rivets, or any attachment mechanisms known in the art. The positions of the latch structure 52 and the engaging structures 82 shown in FIG. 2 are not intended to be limiting, and it is contemplated that the latch structures 52 and the engaging structures 82 may be positioned at other locations. In addition, in one embodiment, the latch structure 52 may be carried by the container portion 16 and the engaging structure 82 may be carried by the cover 18.

In one embodiment, the latch member 24 is constructed and arranged to prevent the latch structure 52 to be moved from the engaged position to the disengaged position when the latch member 24 is in the locked configuration and to permit the latch structure 52 to be moved from the engaged position to the disengaged position when the latch member 24 is in the unlocked configuration. The process of moving the latch structure 52 between the engaged and disengaged position will be described in more detail later.

In the embodiment shown in FIG. 2, the container 16 of the tool container 12 includes a pair of side walls 32 and 34, a front wall 36, and a rear wall 38, and a bottom wall 40. The front wall 36, the rear wall 38 and the opposed side walls 32 and 34 are constructed and arranged to generally extend vertically upwardly from the bottom wall 40. The front wall 36 and the rear wall 38 are joined to each other by the opposed side walls 32 and 34 to form the aforementioned storage space 20 therewithin with the upwardly facing opening 22 in the container 16. In one embodiment, the base container 16 is formed from a suitable molded plastic material.

The cover 18 generally includes a top wall 58, a front wall 60, a rear wall 62, and opposed side walls 64, 66. The front wall 60, the rear wall 62 and the opposed side walls 64 and 66 are constructed and arranged to generally extend vertically downwardly from the top wall 58. The top wall 58 may be provided with strengthening ribs 59 that are deployed crosswise relative to one another. In one embodiment, the cover 18 may be pivotally connected to the side wall 34 of the container 16 using hinge members 70. In one embodiment, the cover 18 may be coupled to the front wall 36 and/or the rear wall 38 of the container 16 using at least one linkage member 68 (one is shown). The linkage member(s) 68 are constructed and arranged to support the cover 18 when the cover 18 is in the open position. The linkage members 68 may also be configured to act as a stop to limit the movement of the cover 18 beyond a maximum open position of the cover 18. In one embodiment, the linkage 68 includes a pneumatic cylinder 65 and piston 67, as illustrated. Piston member 67 may be configured to be received within cylinder member 65 when the cover 18 is in the closed position. The compressed gas within cylinder 65 provides a spring force to retain the cover 18 in the open configuration. In one embodiment, the linkage members 68 are made from a flexible material (such as a chain, wire, rope or string, for example) so that the linkage members 68 are in a slack configuration, when the cover 18 is in the closed position. The linkage members 68 can retain the cover 18 in an upright position after being pivoted upwardly beyond the weight over center position. In another embodiment, the linkage members 68 may take the form of a two bar linkage, pin and slot arrangement, or other type linkage known in the art.

In one embodiment, the tool container 12 optionally includes an extendable handle 42 and rollers 72. The tool container 12 may include an extendable handle and rollers as described in U.S. application Ser. No. 12/165,715, filed on Jul. 1, 2008, hereby incorporated by reference in its entirety. Any of the other features/aspects of U.S. application Ser. No. 12/165,715 may also be used in the present invention. In some embodiments, it is contemplated that the tool container 12 may have similar configurations as the tool containers described in U.S. application Ser. No. 12/683,166 and/or U.S. application Ser. No. 61/087,061, each of which is hereby incorporated by reference in its entirety. In one embodiment, the tool container 12 may include a dock unit 500 of the type illustrated in FIG. 2 and disclosed in U.S. application Ser. No. 12/683,166, which is hereby incorporated by reference in its entirety.

The extendable handle 42 is operatively connected to the container 16 to facilitate tilted rolling transport of the electrically and manually lockable container system 10. The container 16 includes a pair of handle receiving portions formed near a top edge 48 along the opposing side walls 32 and 34. The handle receiving portions are constructed and arranged to receive the handle 42 therewithin, when the handle 42 is in a retracted position. In one embodiment, the handle receiving portions are hollow structures that are configured to telescopically receive legs of the handle 42 to enable extension and retraction respectively. The extendable handle 42 may be moved to an extended position to facilitate tilted rolling transport of the electrically and manually lockable container system 10.

As shown in FIG. 2, the rollers 72 are connected with the container 16 to enable transport of the tool container 12. In one embodiment, the rollers 72 may be in the form of wheels and may facilitate rolling transport of the tool container 12. In one embodiment, the rollers 72 are mounted in a recess 74 formed in the base container 12 so that the container 12 may be tilted and pulled or pushed along a horizontal surface (e.g., ground surface) by the user holding the handle 42. The rollers 72, in one embodiment, may optionally be locked against rolling motion by roller lock members that are operatively connected to the rollers 72 to provide a stationary configuration. Preferably each wheel is a molded structure reinforced by a plurality of wheel ribs (not shown) and each wheel is mounted on an end of an elongated axle by two hubs or other appropriate structure. The axle may be an elongated cylindrical steel shaft that is snap fit into rotational engagement with a receiving structure of the container 16. Alternatively, the axle can be mounted to the tool container 12 through a pair of axially aligned through-holes formed in the rear wall 38 of the container 16.

In one embodiment, the tool container 12 may optionally include a carrying handle (not shown) on the cover 18. The carrying handle may be constructed and arranged to be attached to a top surface of the cover 18. In embodiments where a carrying handle is used, the handle 42 and rollers may optionally be eliminated (and vice versa).

Seal 63 may be provided along the periphery of a rim 61 of the cover 18. Thus, when the cover 18′ is in the closed position, the seal 63 may contact rim 69 of the container 68. Additionally, storage compartments 71 may be provided in the storage space 20 of the container 16. The storage compartments 71 may have various constructions and may be defined by dividers, inserts, or other containers.

In the embodiment shown in FIG. 2, the lock system 14 is attached to the cover 18 of the tool container 12 near the front wall 64, although it is contemplated that the lock system 14 may be positioned in other locations. FIG. 2 also shows components of the lock system 14 disposed in a housing or receiving structure 11. The receiving structure 11 may be constructed of plastic, although other materials, such as, for example, wood, metal, or a combination thereof, may be used. The receiving structure 11 may be attached to an inside surface 57 of the top wall 58 via screws (not shown), although other attachment mechanisms may be used. In one embodiment, the motor 26, the controller 28, a power supply or source 56, the latch structure 52, and the latch member 24 can be disposed in the receiving structure 11. As shown in FIG. 9, the receiving structure 11 may include a sliding portion 151, wherein the latch member 24 slides on the sliding portion 151 when the latch member 24 is moved between the unlocked and locked positions. Retaining members 156 (two are shown in FIG. 10) located on the receiving structure 11 may be constructed and arranged to retain the latch member 24 against wall 157 of the receiving structure 11 when the latch member 24 slides on the sliding portion 151 of the receiving structure 11.

In one embodiment, the latch structure 52 is rotatably connected to the receiving structure 11 via pin 114 (one is shown in FIG. 5). A pair of operating bars 76 may each be pivotably connected to the receiving structure 11 via pins 116 (one is shown in FIG. 5). The operating bars 76 may be constructed and arranged to move the latch structure 52 between the engaged and disengaged positions. A pivotable handle 75 may be provided on the cover 18 and in one embodiment may include a pair of contacting members 132 (one is shown in FIG. 7). The contacting members 132 of the pivotable handle 75 are constructed and arranged to contact a contact portion 131 (see FIG. 7) of the operating bar 76 to move the latch structure 52 from the engaged position to the disengaged position, which will be described in more detail later. A pair of openings 134 (one is shown in FIG. 7) is provided in the receiving structure 11 and constructed and arranged to receive the contacting members 132 of the handle 75 when the handle 75 is pivoted to contact the operating bars 76 in order to move the latch structure 52 from the engaged position to the disengaged position.

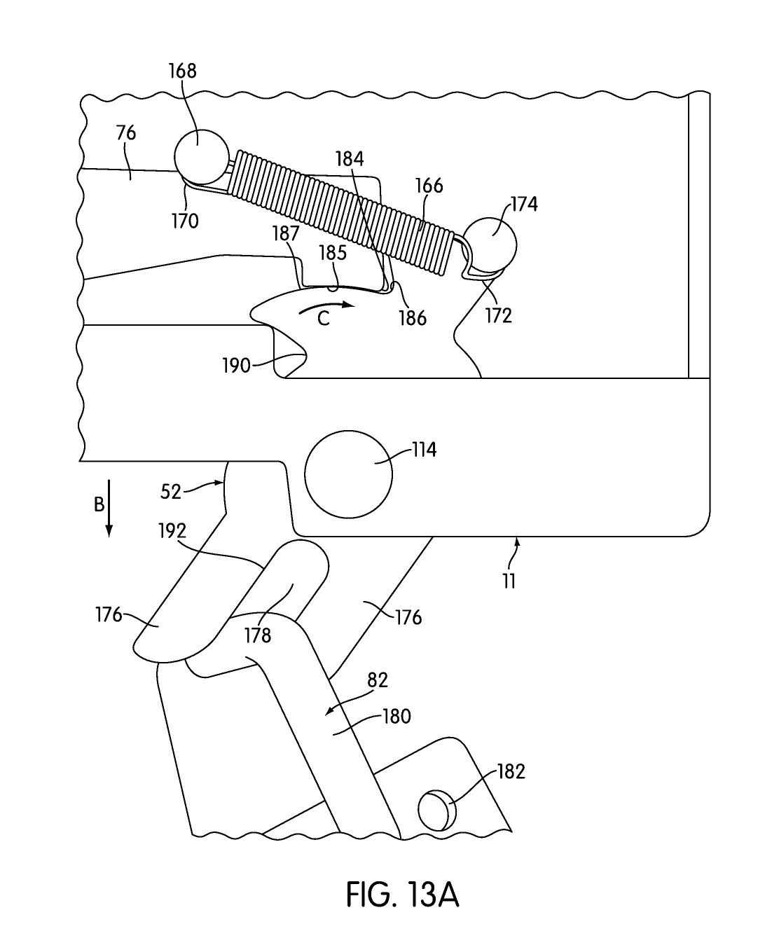

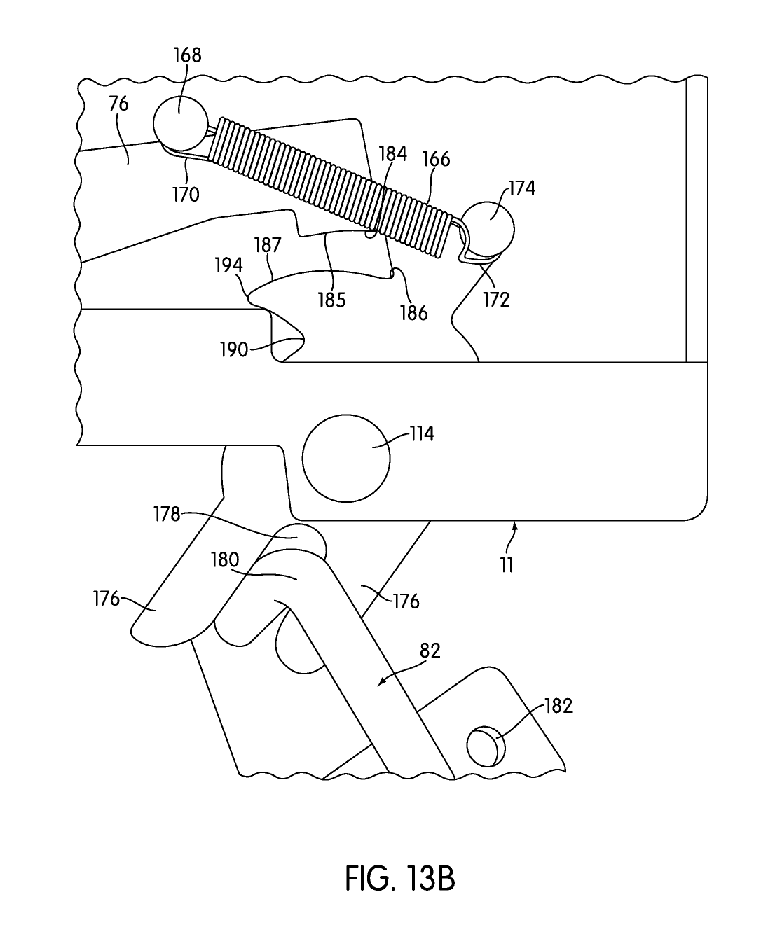

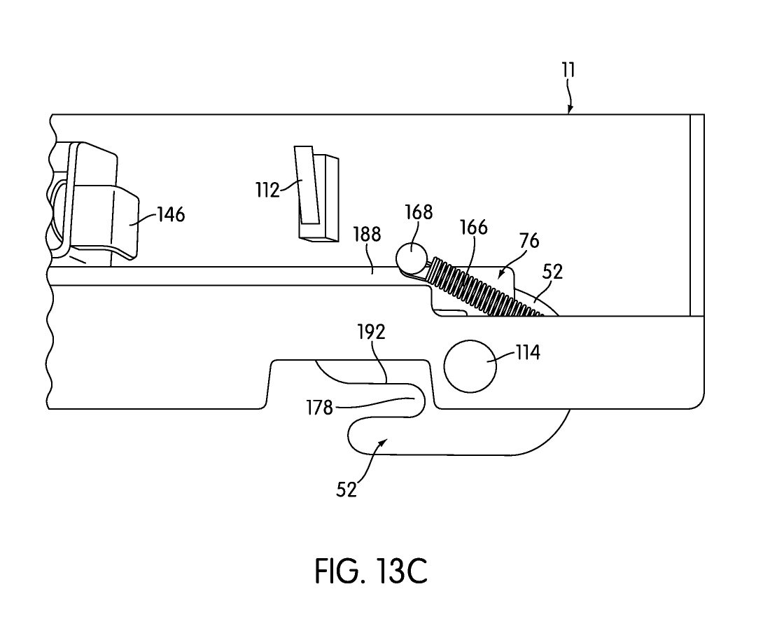

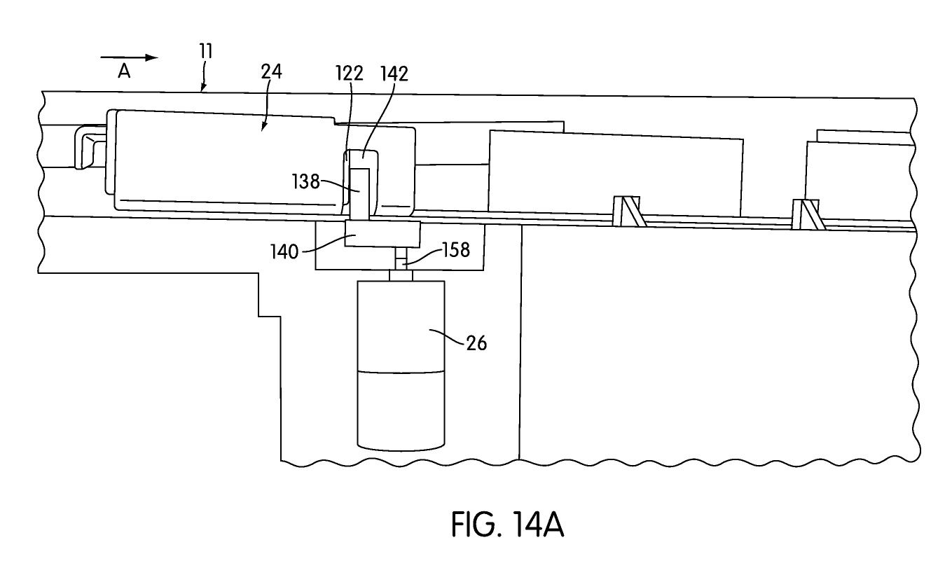

Each operating bar 76 may be attached to one end of a spring 166. For example, in the embodiment shown in FIG. 13B, a first tang 170 of the spring 166 is wound around a projection 168 of the operating bar 76. The other end of the spring 166 includes a tang 172 wound around a projection 174 located on the latch structure 52. In the illustrated embodiment, the latch structure 52 is provided with a first groove 186 and a second groove 190. The first groove 186 and the second groove 190 are constructed and arranged to receive a corner edge 184 of the operating bar 76. The latch structure 52 may also be provided with a curved surface 187 constructed and arranged to contact a curved edge 185 of the operating bar 76. The latch structure 52 is rotatably attached to the receiving structure 11 via the pin 114. The latch structure 52 may also include latching fingers 176 on a side opposite the projection 174. A U-shaped groove 178 is provided between the latching fingers 176. The U-shaped groove 178 is constructed and arranged to receive an insertion portion 180 of the engaging structure 82. In this embodiment, the engaging structure 82 is attached to the container 12 via screws (not shown) that are received in openings 182 (one is shown) provided on the engaging structure 82.

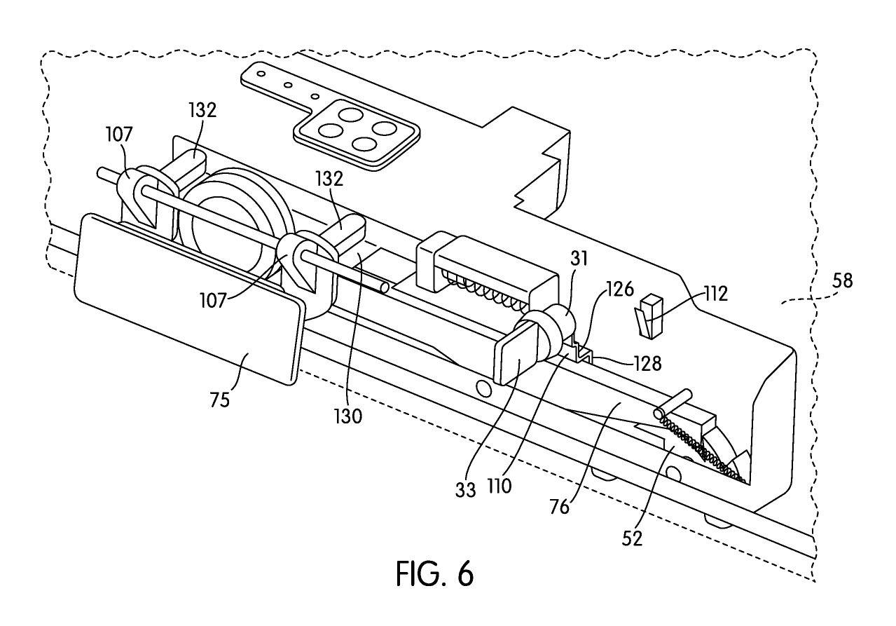

As shown in FIG. 5, the handle 75 may be pivotally mounted to a cover mount 80 via a pivot axle or rod 106. Aesthetic cover 78 may be constructed of metal or plastic and may be constructed and arranged to cover handle mount 80 (see FIG. 2), which may be constructed of plastic. In this embodiment, aesthetic cover 78 is attached to handle mount 80 via screws 108. In the illustrated embodiment, the rod 106 is received in receiving portions (not shown) formed in the handle mount 80. The rod 106 is also received in receiving portions 107 of the handle 75, as shown in FIG. 6. In the embodiment shown in FIG. 5, a spring 108 has central coils 109 thereof wrapped around rod 106. The spring 108 at one end (not shown) thereof is attached to the handle mount 80 and at an other end 111 thereof to the handle 75, and thus biases the pivotable handle 75 towards a default position (or latching position) wherein a front surface 81 of the handle 75 is generally parallel with the side wall 64 of the cover 18, as shown in FIG. 5. The spring 108 is positioned between the receiving portions 107 of the handle 75 when the rod 106 is received in the receiving portions 107 of the handle 75. The handle 75 may be manually pivoted upwards in a clockwise direction against the bias of the spring 108 (towards a releasing position) so as to unlock the latch structure 52, which will be described in more detail later.

Referring back to FIG. 1, the illustrated electrically and manually lockable container system 10 includes a detector, such as a switch 50 (e.g., a microswitch), used to detect the opening or closing of the cover 18. In one embodiment, the switch 50 is depressed, or actuated, when the cover 18 is closed relative to the container 16. Thus, in the embodiment shown in FIG. 1, the switch 50 may be actuated by switch contact member 51 located on the container 16. As such, when the cover 18 is closed and contacts the container 16, the switch 50 is depressed. However, when the cover 18 is lifted away from the container 16, the switch 50 no longer contacts the switch contact member 51. The switch 50 can then send a signal to the controller 28 to indicate that the cover 18 has been moved to the open position. In another embodiment, the switch 50 can send a signal to the controller 28 indicating that the cover 18 has been moved to a closed position. It is contemplated that in some embodiments, a light detector or different types of switches, such as a magnetic switch, may be used. In embodiments wherein a light detector is used, a photo-sensor operates as a detector and detects the ambient light entering the tool container 12, when the cover 18 of the tool container 12 is opened, and provides the input signal to the controller 28. The controller 28 is configured to receive an input signal from the switch 50 based on the detected condition of the tool container 12. In one optional embodiment, an output signal from the controller 28 is generated in response to the input signal from the switch 50, and the output signal may be received by an alarm 54 (see FIG. 5) that is operatively connected to the controller 28.

In one embodiment, the controller 28 is in the form of a microcontroller. Just for example, the microcontroller may include a Microchip PIC18 series architecture. In some embodiments, the controller 28 may include a timer and memory. It is contemplated that the controller 28 may be located anywhere within or on the tool container 12. In one embodiment, the controller 28 is configured to be in an electronic mode and a manual mode. In the electronic mode, the controller 28 can operate the motor 26 and in the manual mode, the controller 28 may optionally be deactivated or disabled. In such embodiments, when the controller 28 is deactivated, the latch member 24 is movable between the locked and unlocked positions manually, such as by using the manual key arrangement 30. In one embodiment, the controller 28 is configured to process the input signals from the detector 24 based on the condition of the tool container 12, such as whether the cover 18 is open or closed, and to generate the output signal to the alarm 54.

In the embodiment shown in FIG. 5, the alarm 54 is attached to the cover 18. However, it is contemplated that the alarm 54 may be located anywhere in or on the tool container 12. The alarm 54 may include a speaker or other sound producing device. In such embodiments, the speaker or other sound producing device, if provided, is constructed and arranged to generate an audio alarm indication in response to the condition of the tool container 12 detected by the switch 50.

In one embodiment, the alarm 54 may generate audio indications such as a siren with five volts buzzer. The audio alarm indication may include, but not limited, to a tone, a buzz, a beep, a sound (e.g., a horn or a chime), and/or a prerecorded voice message. In one embodiment, the audio alarm indication may include tones with changing frequency or volume. In another embodiment, the audio alarm indication may include customer configurable tones and alarms.

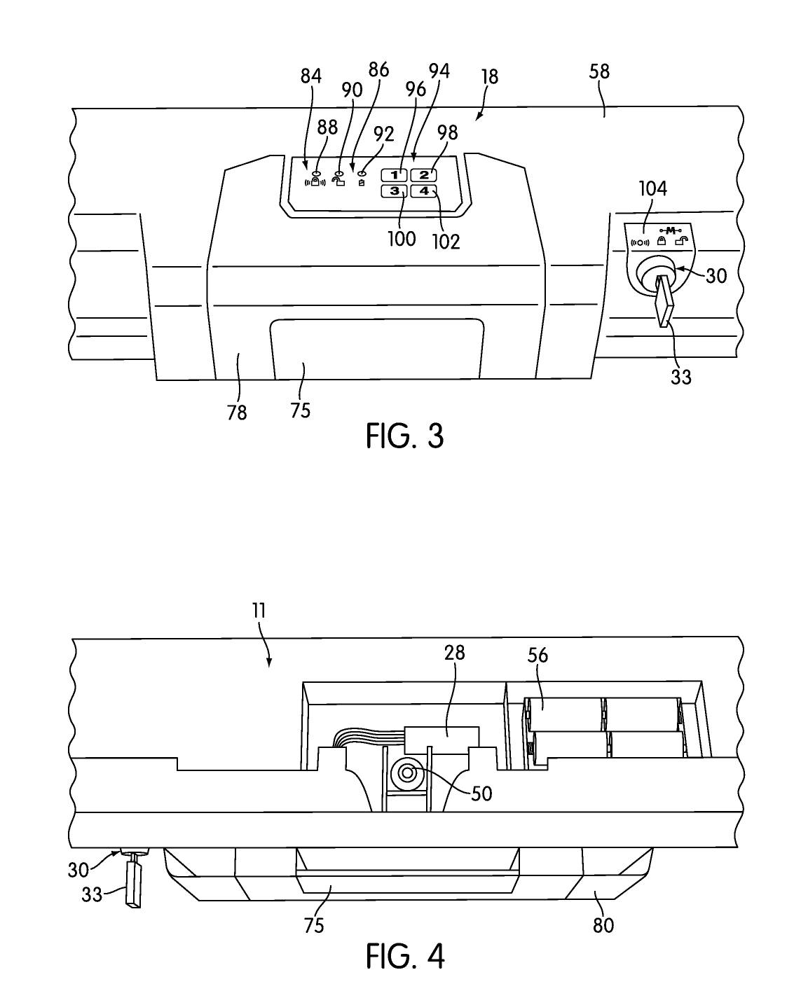

In one embodiment, a visual alarm indication that may be generated by the plurality of illuminators 86 (see FIG. 3). In one embodiment, the plurality of illuminators 86 may include lamps, light emitting diodes and/or liquid crystal displays. In some embodiment, it is contemplated that the plurality of illuminators 86 may be continuous, flashing or strobe lights. Any one or combination of the alarm 54 and plurality of illuminators 86 may be used as signaling devices configured to generate alarm indications.

The power supply 56 (see FIG. 4) may be configured for powering the any one or combination of the controller 28, the alarm 54, and the motor 26. The motor 26 may be connected to the power supply 56 via wires 160 (see FIG. 7). The power supply 56 provides power (directly or indirectly) to any of these components that may require power source to be operated. In one embodiment, the power supply 56 takes the form of batteries, although other types of power supplies may be used, such as, for example, solar cells or an A/C main In one embodiment, four batteries may form the power supply 56. The electrically and manually lockable container system 10 may include hardware configured to measure the voltage condition of the power supply. In such embodiment, the electrically and manually lockable container system 10 is configured to generate a warning indication when a low voltage condition of the power supply 56 is detected. The connections between the switch 50, the controller 28, the motor 26, and the alarm 54 may be hardwired, wireless, or any combination thereof. In one embodiment, when the controller 28 is in the manual mode, the power supply 56 may be disconnected from any one or any combination of the controller 28, the motor 26, a user interface panel 84 (see FIG. 3), or other components of the lock system 14. When power is not available to the electrical components (e.g., because the batteries have run down or because the system 10 has been switched to manual mode), the user may manually lock and unlock the latch member 24.

In one embodiment, as shown in FIG. 3, the tool container and alarm system 10 includes the user interface panel 84 mounted on the cover 18. In one embodiment, the user interface panel 84 is located on the top wall 58 of the cover 18. The user interface panel 84 is operatively connected to the controller 28 to lock or unlock the lock system 12 when the controller 28 is in the electronic mode. The user interface panel 84 includes the plurality of illuminators 86 configured to provide an indication of the condition of the tool container 12. In one embodiment, the plurality of illuminators 86 may include three illuminators, for example, each having a different color. In one embodiment, the plurality of illuminators 86 may include a first illuminator 88, a second illuminator 90, and a third illuminator 92. For example, the first illuminator 88 may include a red LED, a second illuminator 90 may include a green LED, and a third illuminator 92 may include a yellow LED. In this embodiment, when the controller 28 is in the electronic mode and the lock system 14 is in the locked state, the first illuminator 88 is illuminated to signal that the lock system 14 is locked. When the controller 28 is in the electronic mode and the lock system 14 is in the unlocked state, the second illuminator 90 may be illuminated to signal that the lock system 14 is unlocked. Additionally, when the controller 28 is in the electronic mode and the power level of the power supply 56 is low, the third illuminator 92 may be illuminated. In one embodiment, the plurality of illuminators 86 may all be illuminated for a certain amount of time after the electronic mode has been activated to signal the activation of the electronic mode. In one embodiment, the certain amount of time is between 1 to 5 seconds.

The user interface panel 84 comprises a keypad 94, which includes a plurality of user-activated keys. The keys are operatively connected to the controller 28. In this embodiment, the keypad 94 includes numeric user-activated keys 96, 98, 100, and 102 configured to enable a user to enter a valid passcode so as to lock and unlock the lock system 14 in the electronic mode. The passcode or combination code may optionally be changeable by the user.

In one embodiment, the user may change the passcode as follows. After the electronic mode has been activated using the manual key arrangement 30, the user may enter in the current valid passcode via the keypad 94. The second illuminator 90 may blink or flash, at which time, the user may depress key 96 and 98 simultaneously. After the user has released the keys 96 and 98, the third illuminator 92 may blink, thus signaling the user to enter the new passcode via the keypad 94. The lock system 14 may emit a beep or other indication and the third illuminator 92 may blink again, thus prompting the user to enter the new passcode again to confirm the passcode. After the passcode has been successfully entered, the second illuminator 90 can illuminate to indicate that the new passcode has been successfully entered and stored by the controller 28.

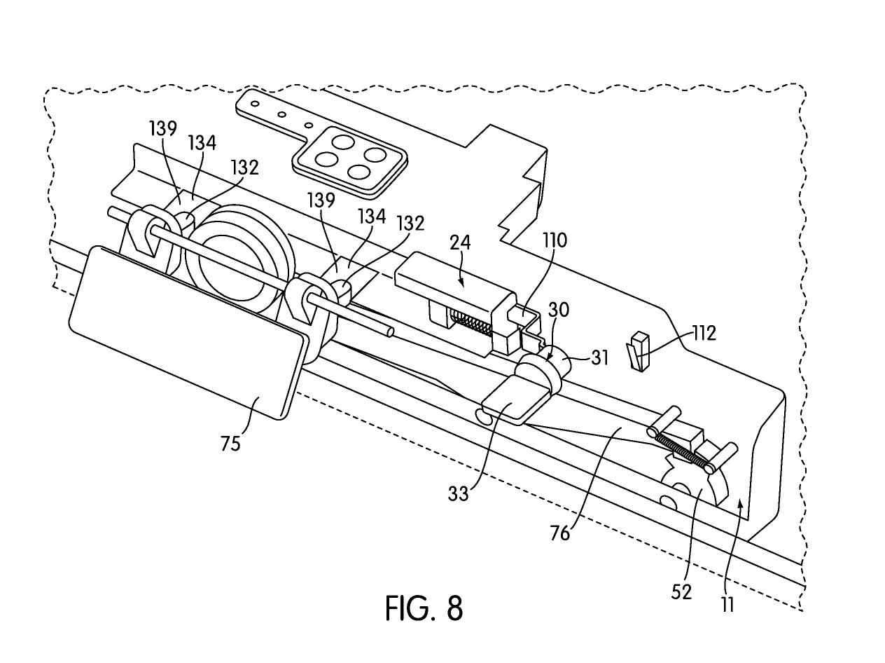

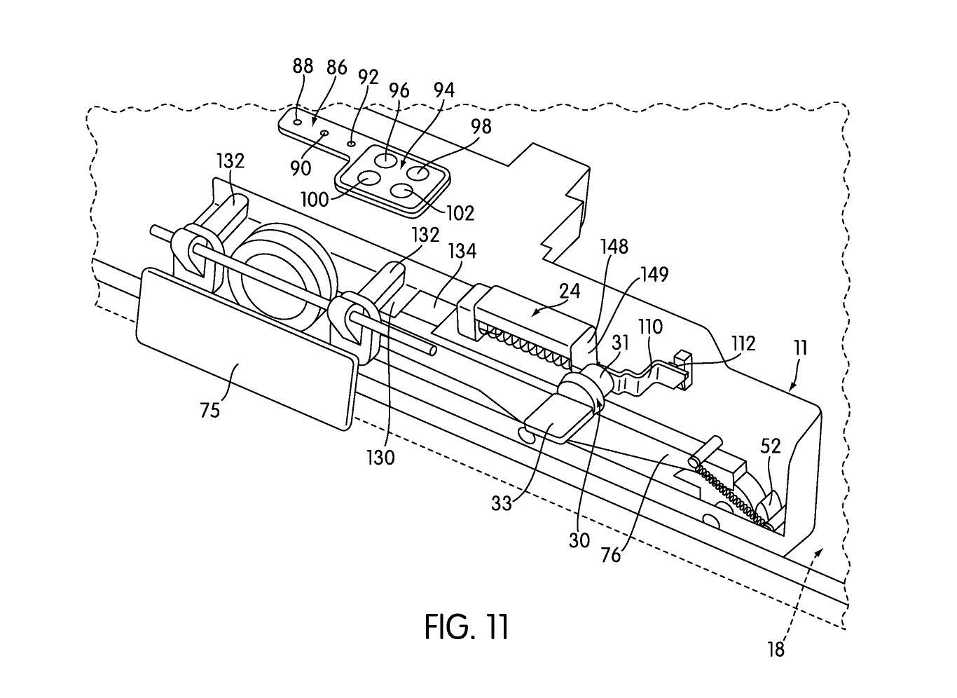

In one embodiment, the user may use the manual key arrangement 30 to change the operating mode between the electronic mode and the manual mode and to lock and unlock the lock system 14 in the manual mode. The manual key arrangement may be located on the second side wall 64 of the cover 18, although other locations can be selected. In one embodiment, the manual key arrangement 30 comprises a key cylinder 31 (see FIG. 5) and a key 33 (see FIG. 5). The key 33 may be inserted into the key cylinder 31 to rotate the key cylinder 31 so as to change the mode of operations (e.g., between the manual mode and the electronic mode). A key panel 104 is provided on the top wall 58 of the cover 18, near the manual key arrangement 30, to indicate the direction the key 33 should be turned so as to change the mode or to unlock/lock the lock system 14. As shown in FIG. 5, the cylinder 31 includes an actuating member 110 used to activate the electronic mode and to move the latch member 24 to the unlocked position. It is contemplated that the actuating member 110 may be a separate attachment or may be integral with the key cylinder 31. The key 33 may be rotated in the clockwise direction (towards the right) from a middle position (see FIGS. 3 and 6), wherein the wide surface of the key is generally perpendicular to the top wall 58 of the cover 18, to unlock the lock system 14 in the manual mode, as shown in FIG. 8. In contrast, to activate the electronic mode, the key 33 may be rotated in the counterclockwise direction (towards the left) from the middle position, as shown in FIG. 11. In this embodiment, when the key 33 is rotated clockwise towards the right position from the middle position, the actuating member 110 is rotated in the clockwise direction towards the left (see FIG. 8). In contrast, when the key 33 is rotated counterclockwise towards the left position from the middle position, the actuating member 110 is rotated in the counterclockwise direction towards the right (see FIG. 11). The actuating member 110 is constructed and arranged to push or cam against the outer surface 149 of the side wall 148 of the latch member 24 when the actuating member 110 is rotated clockwise towards the position shown in FIG. 9.

As shown in FIG. 9, the actuating member 110 may include a ledge portion 126 and an extending portion 128 with the ledge portion 126 and the extending portion 128 being generally perpendicular to one another. The extending portion 128 may include a slanted surface 154 constructed and arranged to contact the side wall 148 of the latch member 24. The ledge portion 126 may have a curved surface 150 extending therefrom. The curved surface 150 is constructed and arranged to contact a contacting portion 152 of the lip 146 of the latch member 24. As noted above, the key 33 may be selectively rotated to various positions to 1) activate the electronic mode, 2) to lock the lock system 14 in the manual mode, or 3) to unlock the lock system 14 in the manual mode. When the key 33 is turned counterclockwise towards the left position (the “electronic mode” position) from the middle position, the actuating member 110 contacts and actuates a mode switch 112 (see FIG. 11), which takes the form of a microswitch in this embodiment. When the mode switch 112 is actuated, the electronic mode is activated.

FIG. 6 shows the controller 28 in the manual mode with the latch member 24 in the locked configuration and the latch structure 52 in the engaged position. In this Figure, the key 33 is in the middle position wherein the actuating member 110 is contacting the operating bar 76. In this position, the ledge portion 126 and extending portion 128 of the actuating member 110 may abut against the operating bar 76. As shown in FIG. 7, the spring 118 biases the latch member 24 in the locked configuration such that the blocking portions 130 (one is shown) of the latch member 24 blocks the contacting members 132 (one is shown) of the handle 75 from contacting the contact portion 131 of the operating bar 76. In the illustrated embodiment, in order for the contacting members 132 to be able to push against the contact portion 131 of the operating bars 72, the openings 134 of the receiving structure 11 should be aligned with the openings 139 of the latch member 24. In contrast, if the openings 134 of the receiving structure 11 are not aligned with the openings 139 of the latch member 24, the blocking portions 130 of the latch member 24 will block the openings 134 of the receiving structure 11 and thus prevent the contacting members 132 of the handle 75 from contacting the contact portion 131 of the operating bars 76. As such, when the latch member 24 is in the locked position, the blocking portions 130 of the latch member 24 may prevent the handle 75 from moving the latch structure 52 from the engaged position to the disengaged position, as shown in FIG. 7.

FIG. 8 shows the controller 28 in the manual mode with the latch member 24 in the unlocked configuration and the latch structure 52 in the disengaged position. In this Figure, the key 33 is in the right (clockwise) position (the “manual unlocked” position) wherein the actuating member 110 is contacting the latch member 24. When moved to this position, as shown in FIG. 9, the extending portion 128 of the actuating member 110 pushes against the side wall 148 of the receiving portion 120 of the latch member 24. A surface 153 (see FIG. 9) of the extending portion 128 is configured to abut against the lip 146 extending from the latch member 24.

Referring to the embodiment shown in FIG. 6, the operation of the lock system 14 when the controller 28 is in the manual mode will be described. As noted above, the latch member 24 may be in the locked state as shown in FIG. 6. In this configuration, the handle 75 cannot be actuated to release latch structures 52. Subsequently, the user may optionally rotate the key 33 clockwise towards the right (the “unlocked manual position”). As the user turns the key 33, the cylinder 31 and the actuating member 110 is rotated in the clockwise direction from their initial position shown in FIG. 6. As the actuating member 110 is rotated, the curved surface 150 extending from the ledge 126 of the actuating member 110 may slide against the contact surface 152 of the lip 146 extending from the latch member 24 (as shown in FIG. 9). Thus, the initial contact between the actuating member 110 and the latch member 24 may occurs when the curved surface 150 of the actuating member 110 contacts the contacting portion 152 of the lip 146 of the latch member 24 to push or cam the latch member 24 to the left. As the actuating member 110 is further rotated clockwise, the slanted surface 154 of the extending portion 128 may contact the surface 149 of the side wall 148 of the latch member 24 to further push or cam the latch member 24 a further distance to the left. The actuating member 110 of the cylinder 31 may then cause the latch member 24 to be pushed towards the handle 75 against the bias of the spring 118. As the latch member 24 is slid in the direction of arrow A, the side wall 148 of the receiving portion 120 is pushed towards the finger 138 of the eccentric 140. As a result, the finger 138 of the eccentric 140 pushes against the sliding member 122 such that the spring 118 is compressed between the sliding member 122 and an inner structure 144 of the receiving portion 120. During the movement of the latch member 24, the finger 138 may be separated from its contact with the flange 162 of the latch member 24. Once the key 33 is fully turned to the “unlocked manual” position, the blocking portions 130 are slid away from the openings 134 such that the openings 134 of the receiving structure 11 are aligned with the openings 139 of the latch member 24, and the latch member 24 is thus in the unlocked configuration. When the latch member 24 is in this unlocked configuration, the contacting members 132 of the handle 75 are able to push against the contacting portions 131 of the operating bars 76 to move the latch structure 52 to the disengaged position.

FIGS. 13A-13C illustrate the operation of the latch structure 52 in more detail. Although the description of the latch structure 52 and the operating bar 76 is described with respect to one of each, the same description may apply to the other latch structure and operating bar 76 not shown in these Figures.

FIG. 13A shows the latch structure 52 in the disengaged position before being moved to the engaged position. In the disengaged position, the latch structure 52 is positioned such that the engaging structures 82 may be inserted or removed from the groove 178 of the latch structure 52. When the latch structure 52 is in the disengaged position, the spring 166 may be in its relaxed (or less stressed) state. In this embodiment, the corner edge 184 of the operating bar 76 is received in the first groove 186 of the latch structure 52. The curved edge 185 of the operating bar 76 abuts against the curved surface 187 of the latch structure 52.

As noted above, the latch structure 52 may be in an engaged position, as shown in FIG. 13C. In the engaged position, the latch structure 52 is positioned such that the engaging structure 82 may not be inserted or removed from the groove 178 of the latch structure 52. In this position, the spring 166 is extended (or more stressed). The fingers 176 of the latch structure 52 are in a horizontal position wherein the fingers 176 are generally parallel with the top surface 188 of the operating bar 76. The edge 184 of the operating bar 76 may be received in the second groove 190 (see FIG. 13B) of the latch structure 52 to prevent counterclockwise rotation of latch structure 52.

The latch structure 52 may be moved from the disengaged position to the engaged position as follows. The latch structure 52 may begin in the disengaged position as shown in FIG. 13A. To move the latch structure 52 to the engaged position, the groove 178 of the latch structure 52 may be aligned with the insertion portion 180 of the engaging structure 82. When the user pushes the cover 18, and thus the receiving structure 11, down towards the container portion 16 in the direction of B, the insertion portion 180 is pushed against a top inner surface 192 of the latch structure 52 that defines the groove 178. The contact between the top inner surface 192 of the latch structure 52 and the insertion portion 180 causes the latch structure 52 to rotate in the clockwise direction C via the pin 114. As the latch structure 52 is rotated in the clockwise direction C, this causes the curved surface 187 of the latch structure 52 to slide against the curved edge 185 of the operating bar 76 in the direction of C. In this embodiment, the rotation of the latch structure 52 in the direction of C causes the distance between the projection 168 of the operating bar 76 and the projection 174 of the latch structure 52 to increase, thus extending the spring 166. The user may push the insertion portion 180 against the top inner surface 192 of the latch structure 52 to rotate the latch structure 52 in the direction of C until the corner edge 184 of the operating bar 76 is positioned to the left of a corner 194 (see FIG. 13B) of the curved surface 187. As such, the corner edge 184 is aligned with the second groove 190 of the latch structure 52, whereupon the spring 166 snaps the operating bar 76 and the latch structure 52 relative to one another so that the corner edge 184 of the operating bar 76 is received within the second groove 190 of the latch structure 52. The latch structure 52 may then be in the engaged position as shown in FIG. 13C. The engaging portion 180 of the engaging structure 82 (not shown in FIG. 13C) may be received in the groove 178 of the latch structure 52.

The latch structure 52 may be moved to the disengaged position as follows. The latch structure 52 may be in the engaged position shown in FIG. 13C. As noted above in some embodiments, to move the latch structure 52 to the disengaged position, the latch member 24 must be in the unlocked position so that the openings 139 of the latch member 24 are aligned with the openings 134 of the receiving structure 11. When the openings 139 of the latch member 24 and the openings 134 of the receiving structure 11 are aligned, the contacting members 132 of the handle 75 can contact and push against the operating bar 76, as shown in FIG. 10. If the latch member 24 is in the unlocked position, as shown in FIGS. 8 and 11, the user may pivot the handle 75 in the upwards direction so that the contacting members 132 of the handle 75 may push against the operating bars 76 and thus pivot the operating bars 76 about the pins 116. Thus, when the contacting members 132 of the handle 75 pushes the contact portion 131 of the operating bar 76 downwards, the other end of the operating bar 76 (with the corner edge 184) is pivoted upwards, as shown in FIG. 13B in a “see-saw” pivoting action of the bar 76 about the pin 116. As such, the corner edge 184 of the operating bar 76 is removed from its contact with the groove or notch 190 of the latch structure 52. As the end of the operating bar 76 with the corner edge 184 is further pivoted upwards, the spring 166 is further extended until the corner edge 184 is lifted past the corner 194 of the curved surface 187 of the latch structure 52, whereupon the spring 166 snaps the latch structure 52 in the counterclockwise direction. The latch structure 52 may be rotated in the counterclockwise direction by the bias of the spring 166 until the corner edge 184 of the operating bar 76 is caught by the first groove 186 of the latch structure 52, as shown in FIG. 13B. The contact between the corner edge 184 of the operating bar and a portion of the latching member 52 thus can prevent the latch member 52 from further rotating in the counterclockwise direction. After the user releases the handle 75, which returns to its default position (as shown in FIG. 5) by the bias of the handle spring 108, the spring 166 can snap the operating bar 76 towards the latch structure 52 so that the corner edge 184 is received within the groove 186 as shown in FIG. 13A. When the latch structure 52 is in the disengaged position as shown in FIG. 13A, the engaging structures 82 may be inserted or removed from the grooves 178 of the latch structures 52. As such, the cover 18 may be moved to the open position.

Referring back to FIG. 8, the latch member 24 may be moved from the unlocked configuration to the locked configuration manually as follows. The latch member 24 may initially be in the unlocked configuration as shown in FIG. 8. The user may turn the key 33 towards the middle position such that the actuating member 110 is rotated in the counterclockwise direction from its position shown in FIG. 9. As the key 33 is rotated, the slanted surface 154 (see FIG. 9) of the actuating member 110 may contact the side wall 148 of the receiving portion 120 of the latch member 24. This enables the spring 118 to bias the latch member 24 in the direction away (opposite of A) from the handle 75. As the key 33 is turned further towards the middle position, the curved surface 150 of the actuating member 110 may slide against the contact surface 152 of the lip 146 extending from the receiving portion 120. The extension of the spring 118 back to its default, relatively relaxed (or less stressed) position may move the side wall 148 of the receiving portion 120 away from the finger 138 of the eccentric 140 so that the position of the finger 138 within the opening 142 is returned to the position shown in FIG. 7. When the key 33 is fully returned to the middle position and the spring 118 is in its relaxed (or less stressed) state, the blocking portions 130 of the latch member 24 is once again blocking the openings 134 to prevent the contacting members 132 of the handle 75 from contacting the operating bars 76.

FIG. 11 shows the controller 28 in the electronic mode and the latch member 24 in the locked configuration. In this embodiment, the key 33 is turned counterclockwise to the left position (the “electronic mode” position) wherein the actuating member 110 is actuating the mode switch 112. As mentioned above, when the mode switch 112 is initially actuated, the plurality of illuminators 86 may all be illuminated for a certain amount of time. The latch member 24 is initially in the locked position wherein the blocking portions 130 of the latch member 24 are positioned above the openings 134 so as to block the contacting members 132 of the handle 75 from entering the openings 134 to contact the operating bars 76. As such, the handle 75 is unable to be pivoted in the upward direction. When the controller 28 is in the electronic mode, the eccentric 140 is in the position as shown in FIG. 14A. The finger 138 of the eccentric 140 is positioned towards the left side of the motor 26, as shown in this Figure. The eccentric 140 may have an opening (not shown) constructed and arranged to receive an axle 158 of the motor 26. As such, the rotation of the axle 158 may rotate the eccentric 140. In this embodiment, the spring 118 is in its relaxed, default position in the receiving portion 120 of the latch member 24.

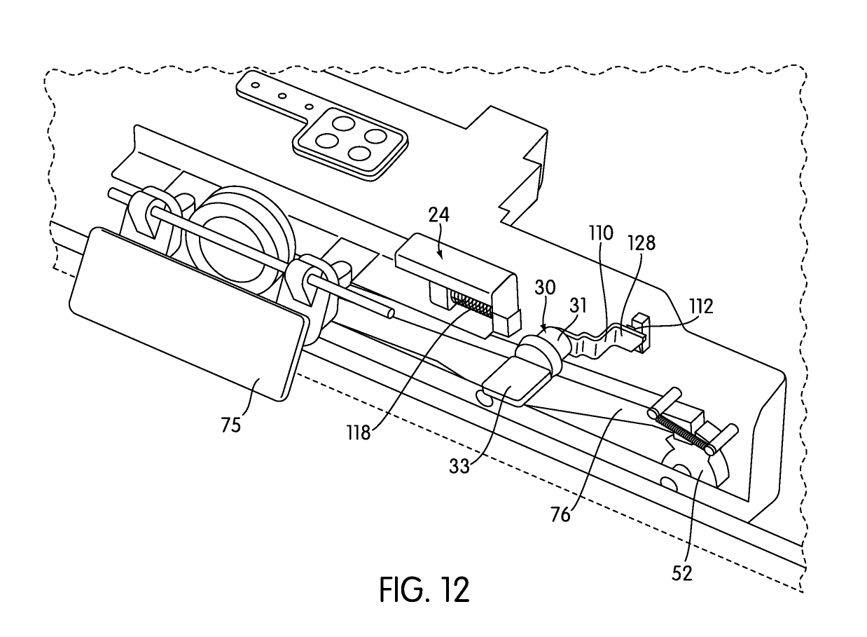

FIG. 12 shows the controller 28 in the electronic mode, the latch member 24 in the unlocked configuration, and the latch structure 52 in the disengaged position. In this Figure, the contacting portion 128 of the actuating member 110 extending from the cylinder 31 is actuating the mode switch 112. The latch member 24 is in a position left of its position when the latch member 24 is in the locked configuration. In this unlocked configuration position, the blocking portions 130 of the latch member 24 are removed from their positions above the openings 134 and the openings 134 of the receiving structure 11 are aligned with the openings 139 of the latch member 24. Thus, the contacting members 132 of the handle 75 are able to be inserted into the openings 134 so as to contact the contacting portions 131 of the operating bars 76. The handle 75 may be pivoted upwards, as shown in FIG. 12. FIG. 14B shows the position of the latch member 24 in more detail when the latch member 24 is in the unlocked configuration in the electronic mode. In this embodiment, the spring 118 is in its relaxed, default position in the receiving portion 120 of the latch member 24. Thus, in one embodiment, the spring 118 is compressed only when the latch member 24 is moved to the unlocked position manually.

When the electronic mode is initially activated by the contact between the actuating member 110 and the mode switch 112, the latch member 24 may be in a locked configuration, as shown in FIG. 11. As mentioned above, the plurality of illuminators 86 may all illuminate for a certain amount of time after the electronic mode has been activated. The first illuminator 88 may blink a certain number of times to indicate that the latch member 24 is in the locked configuration. The latch member 24 can be moved to the unlocked position as follows.

The user may enter the passcode via the keypad 94, which includes the plurality of user-activated keys 96, 98, 100, and 102 in one embodiment. In one embodiment, the first illuminator 88 may blink each time a user pushes a key 96, 98, 100, or 102. When the user has entered the valid passcode, which may comprise a sequence or combination of user-activated key depressions, the second illuminator 90 may illuminate to indicate that the passcode is valid and the user is authorized to move the cover 18 to the open position.

The latch member 24 may initially be in the locked configuration as shown in FIG. 14A before the user has been authorized. As shown in FIG. 14A, the finger 138 of the eccentric 140 that is operatively connected to the motor 26 is received in the opening 142 of the latch member 24. The finger 138 of the eccentric 140 may be positioned between the slider 122 and the flange 162 (see FIG. 7). In one embodiment, the finger 138 of the eccentric may abut against the flange 162 when the latch member 24 is in the locked position and may be moved away from the flange 162 when the latch member 24 is moved to the unlocked position in the manual mode.

After the user has entered a valid passcode, the controller 28 may send a signal to the motor 26 to move the latch member 24 to the unlocked position. The motor 26 may then rotate the axle 158, thus rotating the eccentric 140 (clockwise in FIG. 14A) in the direction of A. The finger 138 of the eccentric 140 is received in the opening 142 of the latch member 24, and thus as the finger 138 is moved in the direction of A by the rotation of the eccentric 140, the finger 138 may pull the latch member 24 in the direction of A. After the eccentric 140 has completed its movement in the direction of A, the finger 138 and the latch member 24 are in their positions as shown in FIG. 14B. In this position, the finger 38 is on an opposite side from its initial position shown in FIG. 14A. The latch member 24 has been moved such that the openings 139 of the latch member 24 are aligned with the openings 134 of the receiving structure 11, thus permitting contacting members 132 of the handle 75 to contact the operating bars 76 to move the latch structure 52 to the disengaged position. The user may then pivot the handle 75 upwards, as shown in FIG. 12 to disengage the latch structure 52 from the engaging structures 82 of the container 16. After the latch structures 52 have been disengaged, the user may then move the cover 18 to the open position.

If the user does not move the cover 18 to the open position after the user has been authorized, the lock system 14 may wait for a certain amount of time before the lock system 14 emits a beep or other signal to indicate that the latch member 24 will soon be moved back to the locked position. In one embodiment, the certain amount of time is 10 seconds.

The latch member 24 may be moved back to the locked position as follows. First, the latch member 24 may be moved back to the locked position automatically if a user does not open the cover 18 after a certain amount of time. Specifically, the controller 28 may send a signal to the motor 26 to rotate the eccentric 140 in the direction opposite of A. The eccentric 140 then rotates (in the counterclockwise direction shown in FIG. 14B) to its position shown in FIG. 14A. During this rotation, the finger 138 of the eccentric 140 pulls the latch member 24 (via the opening 138 of the latch member 24) in the direction opposite of A back to the locked position shown in FIG. 14A.

The latch member 24 may also automatically move back to the locked position after the user has opened the cover 18 and then closed the cover 18. The switch 52 may send signals to the controller 28 after the cover 18 has been opened and after the cover 18 has been closed. After a certain amount of time that the cover 18 has been closed, the controller 28 may then send signals to the motor 26 to rotate the latch member 24 back to the locked position. In some embodiments, the latch member 24 may be moved to the locked position based on user input. For example, the user may use the keypad 94 to signal the controller 28 to move the latch member 24 to the locked position.

If, however, the user attempts to pry open the cover 18 without entering in a valid passcode, and the switch 50 sends a signal to the controller 28 indicating that the cover 18 has been opened without a valid passcode, and thus without authorization, the controller 28 may send a signal to the alarm 54 to generate audio signals to indicate that the electrically and manually lockable container system 10 has been breached (the cover 18 has been opened without authorization). The plurality of illuminators 86 may all illuminate, or blink, to indicate the breach. The alarm 54 and plurality of illuminators 86 may generate signals indicating the breach until a valid passcode is entered or until after a predetermined amount of time has passed.

In some embodiments, the electrically and manually lockable container system 10 may be unlocked by presenting a valid RFID tag or transponder, or actuating a user-actuated key on a hand-held remote transmitter, as described in U.S. Patent Application Ser. No. 61/087,061. In such embodiments, the controller 28 includes a receiver wirelessly communicated with a wireless device, such as a radio-frequency identification tag or transponder. In such embodiment, the radio-frequency identification tag or transponder may include an EM4102 ASK 125 Khz compatible card. In another embodiment, the wireless device is a hand-held remote transmitter. In such embodiment, the transmitter includes a RF transmitter. The hand-held remote transmitter may include user-actuated keys, similar to the user-actuated keys 96, 98, 100, and 102 for locking and unlocking the cover 18 of the tool container 12 electronically. It is also contemplated that the hand-held remote transmitter may include a keypad 84 having other configurations.

Although the invention has been described in detail for the purpose of illustration based on what is currently considered to be the most practical and preferred embodiments, it is to be understood that such detail is solely for that purpose and that the invention is not limited to the disclosed embodiments, but, on the contrary, is intended to cover modifications and equivalent arrangements that are within the spirit and scope of the appended claims. For example, it is to be understood that the present invention contemplates that, to the extent possible, one or more features of any embodiment can be combined with one or more features of any other embodiment.

1. An electrically and manually lockable container system, the container system comprising:
a container, the container including a container portion and a cover, the container portion having a storage space and defining an upwardly facing opening into the storage space; and
the cover being movable between a closed position wherein the cover substantially covers the upwardly facing opening and an open position wherein the upwardly facing opening is substantially exposed, the cover arranged to be selectively disposed in locked or unlocked conditions relative to the container portion; and
a lock system carried by the container system, the lock system comprising a latch member movable between a locked and unlocked configuration, wherein in the locked configuration, the latch member is configured to prevent the cover from being moved from the locked to the unlocked condition relative to the container and wherein in the unlocked configuration, the latch member is configured to permit the cover to be moved from the locked to the unlocked condition relative to the container portion, the lock system comprising:
a motor operatively connected with the latch member;
a controller electrically operable to operate the motor to move the latch member between the locked and unlocked configurations; and
a manual key arrangement to enable the latch member to be manually moved between the locked and unlocked configuration.

2. The electrically and manually lockable container system of claim 1, wherein the controller can be configured to be in an electronic mode and a manual mode, wherein in the electronic mode the controller can operate the motor and in the manual mode the controller is disabled.

3. The electrically and manually lockable container system of claim 1, wherein the lock system further comprises a latch structure movable between an engaged position wherein the latch structure is engaged with the cover to prevent the cover from being moved to the open position and a disengaged position wherein the latch structure is not engaged with the cover to permit the cover to be moved to the open position.

4. The electrically and manually lockable container system of claim 3, wherein the latch structure is operatively connected to a movable bar, and wherein the movement of the movable bar causes the latch structure to move between the engaged and disengaged position.

5. The electrically and manually lockable container system of claim 4, further comprising a movable handle, wherein the movable handle is constructed and arranged to contact the movable bar to move the latch structure between the engaged and disengaged positions.

6. The electrically and manually lockable container system of claim 3, wherein in the locked configuration, the latch member prevents the latch structure to be moved from the engaged position to the disengaged position and wherein in the unlocked configuration, the latch member permits the latch structure to be moved from the engaged position to the disengaged position.

7. The electrically and manually lockable container system of claim 3, further comprising a movable handle constructed and arranged to move the latch structure from the engaged position to the disengaged position.

8. The electrically and manually lockable container system of claim 7, wherein in the locked configuration, the latch member prevents the movable handle from moving the latch structure from the engaged position to the disengaged position.

9. The electrically and manually lockable container system of claim 2, wherein the lock system further comprises a switch movable between an activated state wherein the controller is in the electronic mode and a deactivated state wherein the controller is in the manual mode.

10. The electrically and manually lockable container system of claim 9, wherein the manual key arrangement comprises a key cylinder, and wherein the key cylinder activates the switch when the controller is in the electronic mode.

11. The electrically and manually lockable container system of claim 10, wherein the manual key arrangement further comprises a key constructed and arranged to be inserted into the key cylinder to activate the switch and to move the latch member between the locked configuration and the unlocked configuration manually.

12. The electrically and manually lockable container system of claim 1, further comprising a switch that detects an opening of the cover, and wherein the switch is an electromechanical switch.

13. The electrically and manually lockable container system of claim 1, wherein the latch member comprises a blocking portion constructed and arranged to prevent the cover from being moved to the open position.

14. The electrically and manually lockable container system of claim 2, wherein the motor is deactivated when the controller is in the manual mode.

15. The electrically and manually lockable container system of claim 2, wherein in the electronic mode, an alarm system is switchable between an activated state and a deactivated state.

16. The electrically and manually lockable container system of claim 15, further comprising a switch that detects an opening of the cover, and wherein the switch is an electromechanical switch.

17. The electrically and manually lockable container system of claim 16, wherein the alarm system comprises a signaling device operatively connected to the controller and configured to generate an alarm indication in response to receiving an output signal from the controller, the output signal from the controller being generated in response to an input signal from the switch.

18. The electrically and manually lockable container system of claim 17, wherein the signaling device is configured to generate the alarm indication when the cover is moved to the open position without a valid code as an user input.

19. The electrically and manually lockable container system of claim 15, wherein the lock system comprises a user interface configured to accept user input to move the latch member between the locked and unlocked configurations.

20. The electrically and manually lockable container system of claim 19, wherein the alarm system is in the deactivated state when the user input comprises a valid code.

21. The electrically and manually lockable container system of claim 2, wherein the controller is deactivated when in the manual mode.

22. The electrically and manually lockable container system of claim 1, wherein the lock system further comprises a switch configured to switch the lock system between the manual mode and the electronic mode.

23. The electrically and manually lockable container system of claim 1, wherein the manual key arrangement comprises a key cylinder.

24. The electrically and manually lockable container system of claim 23, wherein the key cylinder manually engages the latch member when the latch member is manually moved to the engaged position.

25. The electrically and manually lockable container system of claim 24, wherein the manual key arrangement further comprises a key constructed and arranged to be inserted into the key cylinder to manually engage the key cylinder with the latch member.

26. The electrically and manually lockable container system of claim 2, further comprising a power supply.

27. The electrically and manually lockable container system of claim 26, wherein in the manual mode, the power supply is disconnected from the controller.

28. The electrically and manually lockable container system of claim 1, wherein the user interface comprises a keypad for entering user input.

29. A manually lockable container system, the container system comprising:
a container, the container including a container portion and a cover, the container portion having a storage space and defining an upwardly facing opening into the storage space; and
the cover being movable between a closed position wherein the cover substantially covers the upwardly facing opening and an open position wherein the upwardly facing opening is substantially exposed; and
a lock system carried by the container system, the lock system having at least two latch structures movable between an engaged and a disengaged position, wherein in the engaged position, the latch structures are configured to prevent the cover from being moved from the closed position to the open position and wherein in the disengaged position, the latch structures are configured to permit the cover to be moved from the closed position to the open position, the lock system further comprising:
at least two movable lock members, each associated with one of the latch structures and configured to retain the associated latch structure in the engaged position, the lock members being movable to enable the latch structures to move to the disengaged position;
a single manual actuator that moves each of the lock members to enable the associated latch structures to move from the engaged position to the disengaged position; and
a spring operatively connected with each latch structure and arranged to bias the associated latch structure to the disengaged position when the associated latch structure is unlatched by the actuator.

30. The manually lockable container system of claim 29, wherein the actuator comprises a manually movable handle, and wherein the movable handle is movable to push the actuator against the lock members to unlatch the latch structures.

31. The manually lockable container system of claim 29, wherein each lock member is pivotally attached to the container system at a pivot point such that the lock member can be pivoted to unlatch the latch structures.

32. The manually lockable container system of claim 29, wherein each latch structure has a first recess constructed and arranged to receive a portion of the associated lock member when the latch structure is in the disengaged position, and wherein each latch structure has a second recess constructed and arranged to receive the portion of the associated lock member when the latch structure is in the engaged position.

33. The manually lockable container system of claim 29, wherein one end of the spring is connected to the associated lock member and another end of the spring is connected to the associated latch structure.

34. The manually lockable container system of claim 29, wherein each lock member comprises a pivotable bar.

35. The manually lockable container system of claim 29, wherein each latch structure has a separate spring associated therewith.
